(19) United States
(12) Patent Application Publication
(10) Pub. No.: US 2021/0309569 A1
(43) Pub. Date: Oct. 7, 2021

(54) METHOD FOR RECOVERING QUARTZ PART AND APPARATUS FOR RECOVERING QUARTZ PART

(71) Applicant: SEMES CO., LTD., Cheonan-si (KR)

(72) Inventor: SU HYUNG LEE, Cheonan-si (KR)

(73) Assignee: SEMES CO., LTD., Cheonan-si (KR)

(21) Appl. No.: 17/223,515

(22) Filed: Apr. 6, 2021

(30) Foreign Application Priority Data
Apr. 7, 2020 (KR) 10-2020-0042075

(51) Int. Cl. C03C 25/66; B01J 19/00

(52) U.S. Cl. CPC C03C 25/66; B01J 2219/00121; B01J 19/0013

(57) ABSTRACT

An apparatus for recovering a quartz part includes a processing tank for providing a space accommodating a hydrofluoric acid aqueous solution such that a quartz part to be processed may be immersed, a liquid supply line supplying the hydrofluoric acid aqueous solution to the processing tank, and a heater heating the hydrofluoric acid aqueous solution in the processing tank.

### CROSS-REFERENCE TO RELATED APPLICATION

A claim for priority under 35 U.S.C. § 119 is made to Korean Patent Application No. 10-2020-0042075 filed on Apr. 7, 2020, in the Korean Intellectual Property Office, the entire contents of which are hereby incorporated by reference.

### FIELD OF THE INVENTION

The present disclosure relates to a method for recovering a quartz part and an apparatus for recovering a quartz part.

### BACKGROUND

Among the internal parts of a substrate processing apparatus that manufactures semiconductors or liquid crystal devices using plasma, the surface of a quartz part is deteriorated due to continuous exposure to a plasma environment and replaced with new quart part when a predetermined amount is consumed. The quartz part, however, is very expensive and thus it is required a method for recovering a quartz part.

A variety of methods for recovering a quartz part have been suggested to remove and recover a deteriorated part.

For example, one of the suggestions includes removing a quartz part from a processing apparatus, physically polishing its surface and recovering the quartz part. But this method has a problem in that cracks or scratches are generated on the surface during the physical polishing process. When reusing or recycling later, particles could be generated in the plasma processing environment. Moreover, the thickness of the quartz part is greatly lost during the physical polishing process, thereby reducing the number of reusable times.

Another suggestion includes recovering a quartz part with high-temperature phosphoric acid or hydrofluoric acid. But these two methods also have the following problems. When processed with high-temperature phosphoric acid heated to 130° C. or higher, nitride contaminants deposited on a quartz surface may be removed, but defects on the quartz surface still remain. When processed with hydrofluoric acid, nitride contaminants deposited on a quartz surface and defects on the quartz surface may be removed at the same time, but it is difficult to control the amount of etching due to a very high etch rate for the quartz.

### SUMMARY

The present disclosure is directed to providing a method for recovering a quartz part and an apparatus for recovering the quartz part which may reduce a thickness loss rate inevitable during a recovering process of the quartz part.

The present disclosure is directed to providing a method for recovering a quartz part and an apparatus for recovering a quartz part which may remove nitration contaminants on a surface of the quartz part and defects of the quartz part at the same time.

The present disclosure is directed to providing a method for recovering a quart part to reduce equipment maintenance costs as the reusable number of times may be increased.

The present disclosure is directed to providing a method for recovering a quartz part and an apparatus for recovering a quartz part to shorten the working time required for recovering a quartz part compared to the prior art.

The purpose of the present disclosure is not limited thereto, and other purposes not mentioned will be clearly understood by those skilled in the art from the following description.

The present disclosure provides a method for recovering a quartz part. In one embodiment, a method for recovering the quartz part to be processed with a material layer composed of silicon and nitrogen on a surface and quartz being exposed to the outside recovers the quartz part to be processed by being exposed to a hydrofluoric acid aqueous solution heated to a first temperature of room temperature or higher.

In one embodiment, the first temperature may range from 60 to 100 degrees Celsius.

In one embodiment, the hydrofluoric acid aqueous solution may contain 5 to 10 wt % of a hydrofluoric acid.

In one embodiment, it may take 1 hour or more to expose the quartz part to be processed to the hydrofluoric acid aqueous solution.

In one embodiment, cleaning the quartz part to be processed by being exposed to the hydrofluoric acid aqueous solution at a second temperature lower than the first temperature may be further comprised before being exposed to the hydrofluoric acid aqueous solution at the first temperature.

In one embodiment, the first temperature may range from 60 to 100 degrees Celsius, and the second temperature may range from room temperature to 60 degrees Celsius.

In one embodiment, it may take 30 minutes or more to expose the quartz part to be processed to the hydrofluoric acid aqueous solution at the second temperature, and it may take 1 hour or more to expose the quartz part to be processed to the hydrofluoric acid aqueous solution at the first temperature.

In one embodiment, the hydrofluoric acid aqueous solution at the second temperature and the hydrofluoric acid aqueous solution at the first temperature may contain 5 to 10 wt % of a hydrofluoric acid.

In one embodiment, the quartz part to be processed may be a dielectric under an antenna of a microwave plasma processing apparatus.

Additionally, the present disclosure provides an apparatus for recovering a quartz part. In one embodiment, an apparatus for recovering a quartz part includes a processing tank for providing a space accommodating a hydrofluoric acid aqueous solution such that a quartz part to be processed may be immersed, a liquid supply line supplying the hydrofluoric acid aqueous solution to the processing tank, and a heater heating the hydrofluoric acid aqueous solution in the processing tank.

In one embodiment, the liquid supply line may supply the hydrofluoric acid aqueous solution to the processing tank at room temperature.

In one embodiment, the controller configured to control the heater is further comprised and the controller may heat the hydrofluoric acid aqueous solution in the processing tank to a first temperature by controlling the heater after the quartz part is immersed in the hydrofluoric acid aqueous solution at room temperature in the processing tank and a first time has elapsed.

In one embodiment, the first temperature may range from 60 to 100 degrees Celsius.

In one embodiment, the hydrofluoric acid aqueous solution supplied by the liquid supply line may contain 5 to 10 wt % of a hydrofluoric acid.

According to an embodiment of the present disclosure, a thickness loss rate inevitable during a recovering process of a quartz part may be reduced.

According to an embodiment of the present disclosure, nitration contaminants on a surface of a quartz part and defects of the quartz part may be removed at the same time.

According to an embodiment of the present disclosure, a maintenance cost of equipment may be reduced as the reusable number of times may be increased.

According to an embodiment of the present disclosure, a working time required for recovering a quartz part may be shortened compared to the prior art.

According to an embodiment of the present disclosure, a recovered quartz part does not have cracks or scratches that may act as particles in a plasma processing environment in the future.

The effects of the present disclosure are not limited to the aforementioned effects, and effects not mentioned will be clearly understood by those skilled in the art from the present specification and the accompanying drawings.

### BRIEF DESCRIPTION OF THE FIGURES

FIG. 1 shows a cross-sectional view of a quartz part to be processed.

FIG. 2 is a view of exposing a quartz part to be processed to a hydrofluoric acid aqueous solution at a first temperature according to the first embodiment.

FIG. 3 is a cross-sectional view of a quartz part to be processed which is exposed to a hydrofluoric acid aqueous solution at a first temperature according to the first embodiment.

FIG. 4 is a view of exposing a quartz part to be processed to a hydrofluoric acid aqueous solution at a second temperature according to the second embodiment.

FIG. 5 is a cross-sectional view of a quartz part to be processed which is exposed to a hydrofluoric acid aqueous solution at a second temperature according to the second embodiment.

FIG. 6 is a view of exposing a quartz part to be processed which is already exposed to a hydrofluoric acid aqueous solution at a second temperature to a hydrofluoric acid aqueous solution at a first temperature according to the second embodiment.

FIG. 7 is a cross-sectional view of a quartz part to be processed by being exposed to a hydrofluoric acid an aqueous solution at a first temperature after being exposed to a hydrofluoric acid aqueous solution at a second temperature according to the second embodiment.

FIG. 8 is a schematic view of an apparatus of recovering a quartz part according to an embodiment of the present disclosure.

### DETAILED DESCRIPTION

Hereinafter, embodiments of the present disclosure will be described in more detail with reference to the accompanying drawings. The embodiments of the present disclosure may be modified in various forms, and the scope of the present disclosure should not be construed as being limited to the following embodiments. This embodiment is provided to more completely describe the present disclosure to those skilled in the art. Therefore, the shapes and other features of the element in the drawings are exaggerated in order to emphasize a clearer description.

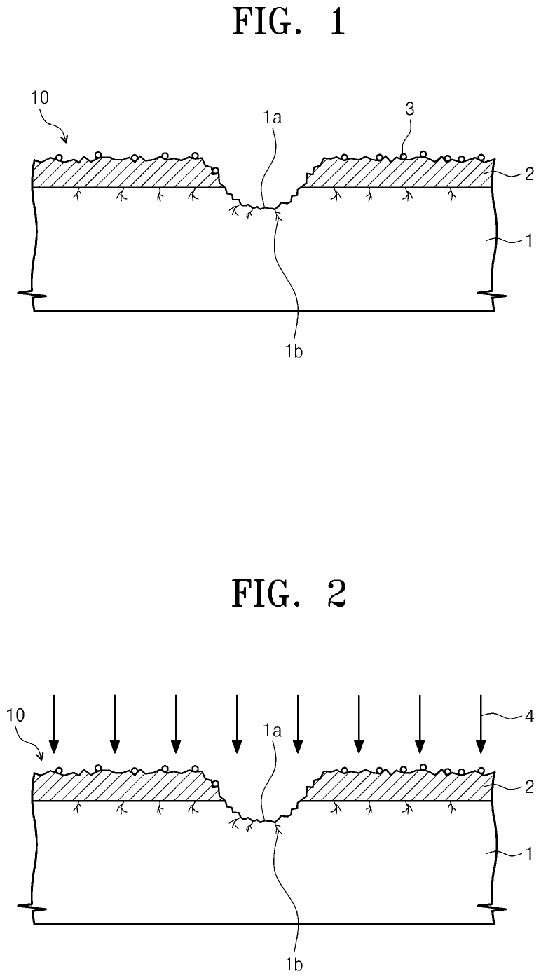

FIG. 1 shows a cross-sectional view of a quartz part 10 to be processed.

The quartz part 10 to be processed has nitride contaminants corresponding to a material layer composed of silicon and nitrogen and an etched quartz surface being exposed to the outside. In one example, the quartz part 10 to be processed may be a dielectric under an antenna of the microwave plasma processing apparatus. For information on the microwave plasma processing apparatus and the antenna and dielectric provided thereto, it is clearly understood with reference to an antenna and dielectric block of Korean Unexamined Patent Publication No. 10-2013-0122497 (KR10-2013-0122497A), which is a document filed and published by the present applicant.

For the quartz part 10 to be processed, a surface of quartz layer 1 made of quartz and a material layer 2 composed of silicon and nitrogen are exposed to the outside. As the surface of the quartz layer 1 is exposed to and etched by a plasma processing apparatus, an etched surface 1a may be formed. And, a defect 1b exists on the surface of the quartz layer 1. Moreover, a material layer 2 composed of silicon and nitrogen generated in a plasma processing apparatus is deposited on the surface of the quartz layer 1.

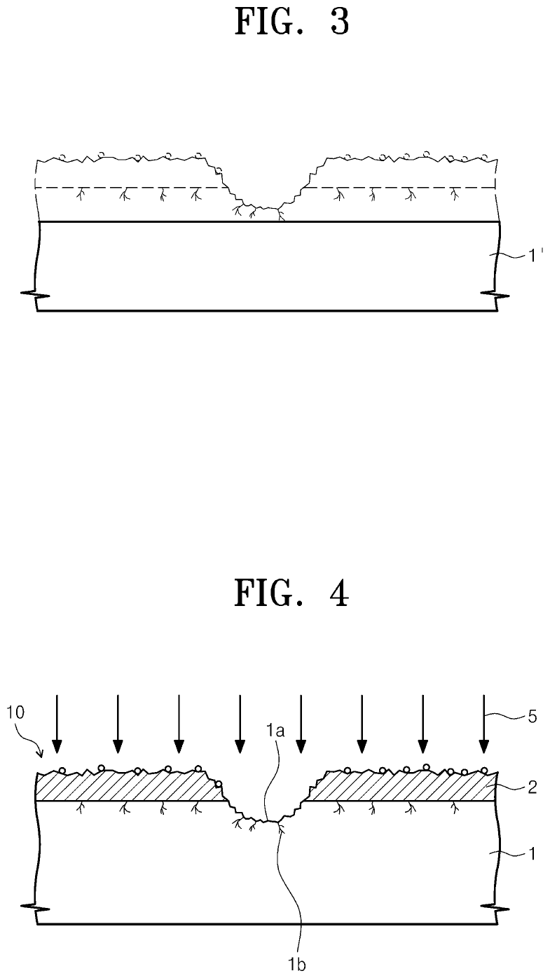

FIG. 2 is a view of exposing a quartz part 10 to be processed to a hydrofluoric acid aqueous solution 4 at a first temperature, and FIG. 3 is a cross-sectional view of a quartz part to be processed which is exposed to a hydrofluoric acid aqueous solution at a first temperature. A first embodiment of the present disclosure will be described with reference to FIGS. 2 and 3.

When the quartz part 10 to be processed is exposed to the hydrofluoric acid aqueous solution 4 at a first temperature, a material layer 2 is etched and removed, and a quartz layer 1 is also etched to remove a defect 1b. A method of exposing the quartz part 10 to be processed to the hydrofluoric acid aqueous solution 4 may be provided in various ways, but it may be immersed as shown in FIG. 8 as an example.

After adjusting concentration of the hydrofluoric acid aqueous solution 4, the hydrofluoric acid aqueous solution 4 is provided as a low concentration hydrofluoric acid aqueous solution. In one embodiment, the low concentration hydrofluoric acid aqueous solution contains 5 to 10 wt % of a hydrofluoric acid. The low concentration hydrofluoric acid aqueous solution has a high content of monofluoride (F—). The higher the content of monofluoride in the hydrofluoric acid aqueous solution, the higher the removal rate of the material layer 2 composed of silicon and nitrogen. But as the low concentration hydrofluoric acid aqueous solution may not sufficiently etch the quartz layer 1, the temperature is controlled to a first temperature.

According to one embodiment of the present disclosure, the first temperature is between 60 to 100 degrees Celsius (° C.). The low concentration hydrofluoric acid aqueous solution 4 heated to the first temperature may etch the quartz layer 1. As a result, the quartz layer 1 is etched by a certain amount to remove the defect 1b.

An exposure time of the quartz part 10 to be processed to the low concentration hydrofluoric acid aqueous solution 4 heated to the first temperature may be different depending on the thickness of the material layer 2 to be etched, the depth of the etched surface 1a, and the depth of the defect 1b. It is appropriate to take 1 hour or more to expose the quartz part 10 to be processed to the low concentration hydrofluoric acid aqueous solution 4 heated to the first temperature. According to an experiment conducted by the present inventors, it takes 1 hour or more to 5 hours or less to expose the quartz part 10 to be processed to the hydrofluoric acid aqueous solution 4 until the surface of the quartz part 10 to be processed is processed to be a recovered quartz part 1′ with an appropriate roughness.

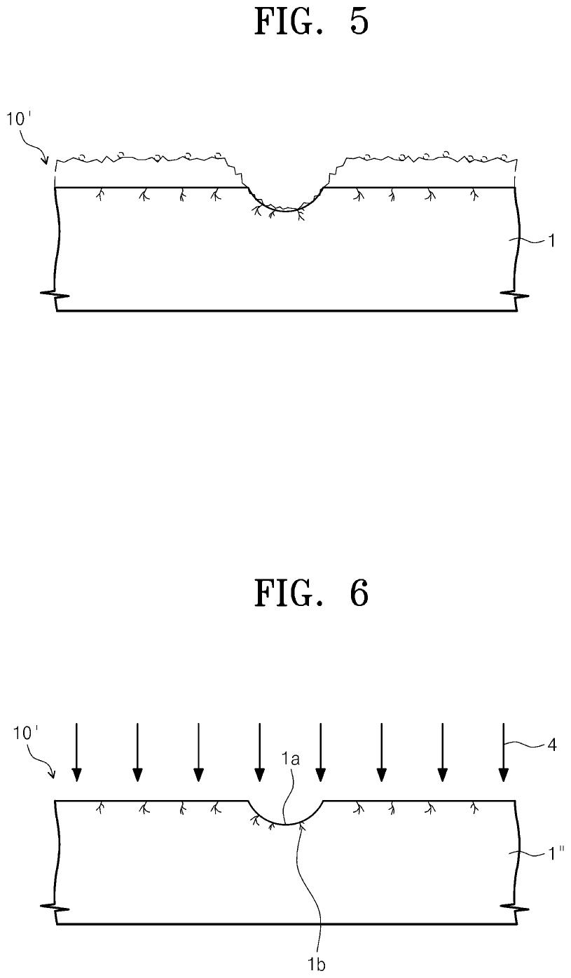

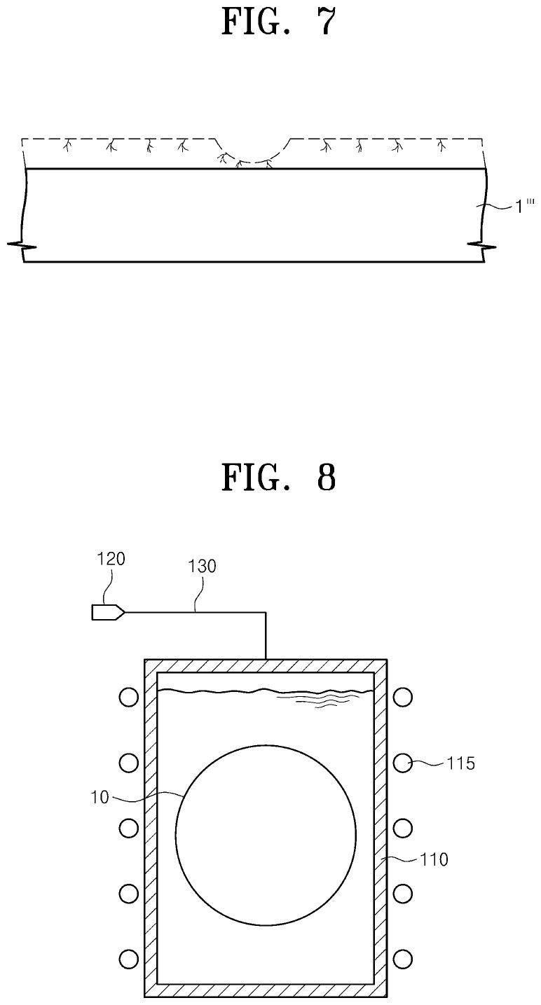

FIG. 4 is a view of a quartz part to be processed by being exposed to a hydrofluoric acid aqueous solution at a second temperature. FIG. 5 is a cross-sectional view of a quartz part to be processed which is already exposed to a hydrofluoric acid aqueous solution at a second temperature. FIG. 6 is a view of exposing a quartz part to be processed which is already exposed to a hydrofluoric acid aqueous solution at a second temperature to a hydrofluoric acid aqueous solution at a first temperature. FIG. 7 is a cross-sectional view of a quartz part to be processed by being exposed to a hydrofluoric acid aqueous solution at a first temperature after being exposed to a hydrofluoric acid aqueous solution at a second temperature. Hereinafter, a second embodiment of the present disclosure will be described with reference to FIGS. 4 to 7 in order.

As shown in FIG. 4, when the quartz part 10 to be processed is exposed to a hydrofluoric acid aqueous solution 5 at a second temperature, the material layer 2 is etched and removed. A method of exposing the quartz part 10 to be processed to the hydrofluoric acid aqueous solution 5 may be provided in various ways, but it may be immersed as shown in FIG. 8 as an example.

After adjusting concentration of the hydrofluoric acid aqueous solution 5, the hydrofluoric acid aqueous solution 5 is provided as a low concentration hydrofluoric acid aqueous solution. In one embodiment, the low concentration hydrofluoric acid aqueous solution contains 5 to 10 wt % of a hydrofluoric acid. The low concentration hydrofluoric acid aqueous solution has a high content of monofluoride (F—) in the hydrofluoric acid aqueous solution. The higher the content of monofluoride in the hydrofluoric acid aqueous solution, the higher the removal rate of the material layer 2 composed of silicon and nitrogen. The second temperature ranges from room temperature to 60 degrees Celsius. The second temperature is room temperature in an unheated state. Since the hydrofluoric acid aqueous solution at the second temperature does not sufficiently etch the quartz layer 1, the material layer 2 is only removed by adjusting the selectivity.

Depending on the thickness of the material layer 2 to be etched in the quartz part 10 to be processed, an exposure time to the hydrofluoric acid aqueous solution 5 at the second temperature may be different. But it is appropriate to take 30 minutes or more for exposing the quartz part 10 to be processed to the second temperature of the hydrofluoric acid aqueous solution 5. According to an experiment conducted by the present inventors, as shown in FIG. 5, it takes 30 minutes or more to 2 hours or less to expose the quartz part 10 to be processed to the hydrofluoric acid aqueous solution 5 until the surface of the quartz part 10 to be processed is processed to remove the material layer 2.

As shown in FIG. 6, when a quartz part 10′ to be processed from which a material layer 2 is removed is exposed to a hydrofluoric acid aqueous solution 4 at a first temperature, a quartz layer 1 is etched away. A method of exposing the quartz part 10′ to be processed to the hydrofluoric acid aqueous solution 4 may be provided in various ways, but it may be immersed as shown in FIG. 8 as an example.

The hydrofluoric acid aqueous solution 4 may be provided by heating a hydrofluoric acid aqueous solution 5 to a first temperature. In one embodiment, the first temperature ranges from 60 to 100 degrees Celsius. The hydrofluoric acid aqueous solution 4 at the first temperature may etch the quartz layer 1. As a result, a quartz layer 1″ is etched by a certain amount to remove a defect 1b.

An exposure time of the quartz part 10′ to be processed to the hydrofluoric acid aqueous solution 4 at the first temperature may be different depending on the depth of an etched surface 1a and the depth of the defect 1b. But it is appropriate to take at least 1 hour for exposing the quartz part 10′ to be processed to the low concentration hydrofluoric acid aqueous solution 4 heated to the first temperature. According to an experiment conducted by the present inventors, it takes 1 hour or more and 3 hours or less for exposing the quartz part 10 to be processed to the hydrofluoric acid aqueous solution 4 until the surface of the quartz part 10′ to be processed is processed to be a recovered quartz layer 1′″ with an appropriate roughness.

FIG. 8 is a schematic view of an apparatus for recovering a quartz part according to an embodiment of the present disclosure.

An apparatus for recovering a quartz part comprises a processing tank 110, a liquid supply line 130, and a heater 115.

The processing tank 110 is configured to be able to accommodate a hydrofluoric acid aqueous solution and provide a space in which the quartz part to be processed may be immersed. The liquid supply line 130 is configured to supply a hydrofluoric acid aqueous solution to the processing tank 110. The hydrofluoric acid aqueous solution supplied by the liquid supply line 130 may have an adjusted concentration. The hydrofluoric acid aqueous solution supplied by the liquid supply line 130 may contain 5 to 10 wt % of a hydrofluoric acid. The liquid supply line 130 may be connected to the liquid supply source 120 to supply the hydrofluoric acid aqueous solution accommodated in the liquid supply source 120 to the processing tank 110. The liquid supply line 130 may supply a hydrofluoric acid aqueous solution to the processing tank 110 at room temperature. A heater 115 is configured to heat the hydrofluoric acid aqueous solution in the processing tank 110. A controller (not shown) is configured to control the heater 115.

Hereinafter, a method of recovering the quartz part 10 to be processed using an apparatus for recovering a quartz part will be described according to an exemplary embodiment. First, a hydrofluoric acid aqueous solution at room temperature supplied by the liquid supply line 130 is accommodated in the processing tank 110. When the processing tank 110 is filled with an appropriate amount of a hydrofluoric acid aqueous solution, the quartz part 10 to be processed is immersed therein. When a first time has elapsed after the quartz part 10 to be processed is immersed, a controller (not shown) controls the heater 115 to heat the hydrofluoric acid aqueous solution in the processing tank 110 to the first temperature. The quartz part 10 to be processed is further immersed in a hydrofluoric acid aqueous solution heated to the first temperature for a second time. The first time may range from 30 minutes or more to 2 hours or less, and the second time may range from 1 hour or more to 3 hours or less. The first temperature may range from 60 to 100 degrees Celsius.

According to the aforementioned apparatus and method, it is possible to remove nitride contaminants of the quartz part to be processed without a separate fine polishing process and to remove defects of the quartz at the same time. Furthermore, the surface roughness may be improved. Moreover, it is available for reduction of operation time and manufacturing cost by omitting the fine polishing process. Additionally, the recovered quartz part according to the aforementioned apparatus and method does not have cracks or scratches that may act as a particle in a plasma process environment in the future. Additionally, when the quartz part is recovered according to the aforementioned apparatus and method, the thickness loss rate inevitable during the recovering process of the quartz part may be reduced, so that the reusable number of times may be increased, and the maintenance cost of the equipment may be reduced.

The detailed description above is illustrative of the present disclosure. Additionally, the aforementioned description shows and describes preferred embodiments of the present disclosure, and the present disclosure may be used in various other combinations, modifications, and environments. That is, changes or modifications may be made within the scope of the disclosure in the present specification and the scope equivalent to the disclosed contents, and/or the skill or knowledge of the art. The aforementioned embodiments describe the best state for implementing the technical idea of the present disclosure, and various changes required in the specific application fields and uses of the present disclosure are also available. Therefore, the detailed description of the disclosure is not intended to limit the disclosure to the disclosed embodiment. Additionally, the appended claims should be construed as including other embodiments

1.-10. (canceled)

11. An apparatus comprising:
a processing tank for providing a space configured to be able to accommodate a hydrofluoric acid aqueous solution such that the quartz part to be processed may be immersed;
a liquid supply line configured to supply the hydrofluoric acid aqueous solution to the processing tank; and
a heater configured to heat the hydrofluoric acid aqueous solution in the processing tank.

12. The apparatus of claim 11,
wherein the liquid supply line is configured to supply the hydrofluoric acid aqueous solution to the processing tank at room temperature.

13. The apparatus of claim 11, further comprising a controller configured to control the heater, wherein the controller heats the hydrofluoric acid aqueous solution in the processing tank to a first temperature by controlling the heater after the quartz part to be processed is immersed in the hydrofluoric acid aqueous solution at room temperature in the processing tank and a first time has elapsed.

14. The apparatus of claim 11,
wherein the first temperature ranges from 60° C. to 100° C.

15. The apparatus of claim 11,
wherein the hydrofluoric acid aqueous solution supplied by the liquid supply line contains 5 to 10 wt % of a hydrofluoric acid.
